(19) United States
(12) Patent Application Publication
(10) Pub. No.: US 2005/0236636 A1
(43) Pub. Date: Oct. 27, 2005

(54) GaN-based light-emitting diode structure

(75) Inventors: Schang-Jing Hon, Bader City (TW); Mu-Jen Lai, Chuagli City (TW); Chi-Feng Chan, Ping Cheng City (TW); Jenn-Bin Huang, Ping Cheng City (TW); Chen-Fu Chiang, Ping Cheng City (TW)

Correspondence Address: TROXELL LAW OFFICE PLLC;SUITE 1404, 5205 LEESBURG PIKE, FALLS CHURCH, VA, 22041, US

(73) Assignee: Supernova Optoelectronics Corp.

(21) Appl. No.: 10/829,934

(22) Filed: Apr. 23, 2004

(51) Int. Cl. H01L 33/00

(52) U.S. Cl. 257/99; 257/103

(57) ABSTRACT

In a GaN-based light-emitting diode structure, a transparent conductive oxide layer is formed as a window layer on a GaN contact layer having a surface textured layer, and the textured layer acts as an ohmic contact layer with the transparent conductive oxide layer. Therefore, it is possible to reduce effectively the contact resistance and the working voltage, while the optical guiding effect is interrupted by the textured layer, to obtain thereby an enhancement of light extraction efficiency and thus an increase in the external quantum yield.

### BACKGROUND OF THE INVENTION

1. Field of the Invention

The present invention relates to a GaN-based light-emitting diode structure, and particularly, to a GaN-based light-emitting diode structure having an improved ohmic contact layer.

2. Description of the Related Art

Referring to FIG. 1, a conventional gallium nitride-based light-emitting diode structure 10 is shown to comprise a substrate 11, a GaN buffer layer 12, an n-type GaN layer 13, an InGaN emitting layer 14, a p-type GaN layer 15, a p-type GaN contact layer 16 and a transparent conductive layer 17. The layers 12 to 16 are herein referred to as an “epitaxial structure”. Further, a p-type metal electrode 18 is disposed on the transparent conductive layer 17 and an n-type metal electrode 19 is disposed on the n-type GaN layer 13.

Conventionally, a p-type gallium nitride ohmic contact layer 16 has a poor conductivity; in other words, the current tends to be confined to a region beneath the p-type metal electrode 18. Therefore, in order to distribute effectively the current to obtain a uniform luminance, a transparent conductive layer 17 is disposed on the p-type GaN ohmic contact layer 16 and covering the entire light-emitting region. In addition, the transparent conductive layer 17 is made extremely thin to obtain a better transparency. According to the prior art, the transparent conductive layer may consist of Ni/Au and a textured pattern is formed on the surface of a light-emitting diode to increase the light-extracting efficiency. In the case of using thin Ni/Au as a transparent conductive layer, an uneven lateral current distribution occurs, resulting in partial light emission and an increase of working voltage, as shown in the combination of a Ni/Au transparent conductive layer and a textured surface and the I-V curve in Attachment 1.

Indium tin oxide (ITO) is a material with a high energy bandgap ranging from 2.9 to 3.8 eV and with a transmittance up to 95% or more in the visible light range. In addition, indium tin oxide is an n-type conductive material with high conductivity and with a refractive index ranging from 1.7 to 2.2. In accordance with Snell's law and anti-reflection theory, due to the distribution of the refractive index (n=2.4) of the multi-layer gallium nitride epitaxial structure and the refractive index (n=1.5) of the resin packaging material, if an intermediate medium having a refractive index n−1.9 is added to the structure, then the reflection can be reduced and thus light extraction efficiency can be enhanced after packaging. For this reason, this material is very suitable for a window layer of a light-emitting diode.

Recently, solutions using indium tin oxide (ITO) as a transparent conductive layer, such as that disclosed in Taiwanese Patent Publication No. 461126, titled “Indium gallium nitride light-emitting diode”, have been proposed. As shown in FIG. 2, the diode structure 20 comprises a substrate 21, a GaN buffer layer 22, an n-type GaN layer 23, an InGaN active layer 24, a p-type GaN layer 25, a p-type contact layer 26, a transparent conductive oxide layer 27, a p-type electrode 28 and an n-type electrode 29. In the structure, the transparent conductive oxide layer 27 is made of indium tin oxide, which is advantageous for light emission. However, in the diode structure, when the underlying p-type contact layer has a flat Ga-polarization surface, it is difficult to form an excellent ohmic contact with the indium tin oxide. Consequently, high contact resistance and poor ohmic contact property makes it impossible to lower the working voltage of the light-emitting diode.

In view of the above disadvantages of poor ohmic contact property and high working voltage, there is a need to develop a structure to improve the ohmic contact property between an indium tin oxide layer and a p-type GaN-based layer.

### SUMMARY OF THE INVENTION

The invention provides a GaN-based light-emitting diode structure having an improved ohmic contact layer, and the purpose of the invention is to form a transparent conductive oxide layer on a GaN contact layer having a surface textured layer and to provide a textured layer to act as an ohmic contact layer with the transparent conductive oxide layer. The light-emitting diode structure includes: a substrate; a semiconductor stacked layer structure disposed on the substrate and having an n-type GaN-based layer, an emitting layer and a p-type GaN-based layer arranged sequentially from bottom to top; a textured layer disposed on the p-type GaN-based layer; a transparent conductive oxide layer disposed on the textured layer and forming an ohmic contact with the textured layer; a first electrode electrically coupled with the n-type GaN-based layer in the semiconductor stacked layer structure; and a second electrode electrically coupled with the transparent conductive oxide layer.

### BRIEF DESCRIPTION OF THE DRAWINGS

Features and advantages of the present invention will be fully understood from the detailed description to follow taken in conjunction with the examples as illustrated in the accompanying drawings, which are to be considered in all respects as illustrative and not restrictive, wherein:

FIG. 1 schematically shows a GaN-based light-emitting diode structure according to the prior art;

FIG. 2 schematically shows an InGaN light-emitting diode structure according to the prior art;

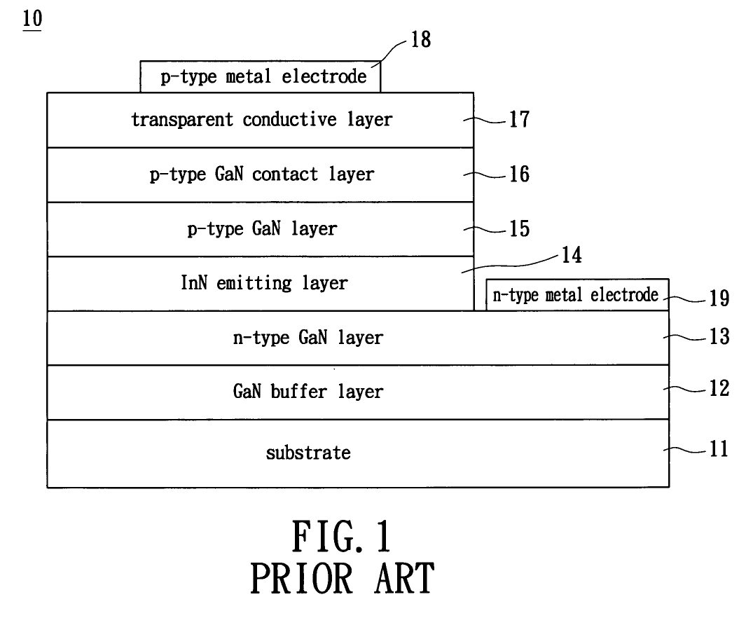

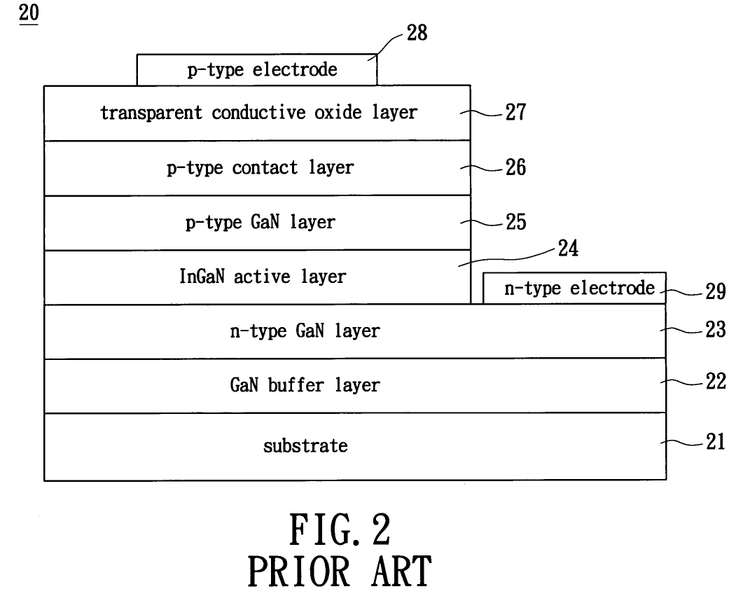

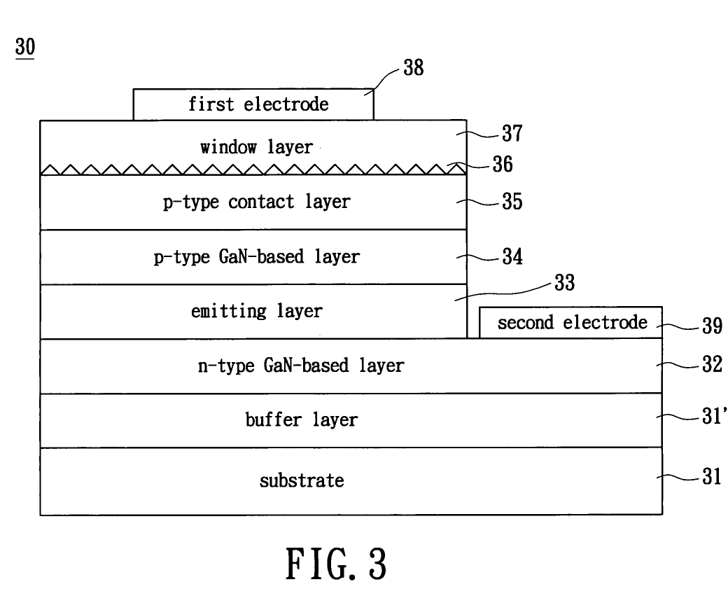

FIG. 3 schematically shows a GaN-based light-emitting diode structure according to the present invention;
Attachment 1 shows a combination of a Ni/Au transparent conductive layer and a textured surface and an I-V curve; and

Attachment 2 shows a combination of an ITO transparent conductive layer and a textured surface and an I-V curve.

### DETAILED DESCRIPTION OF PREFERRED EMBODIMENTS

With reference to FIG. 3, a preferred example of a GaN-based light-emitting diode structure according to the present invention will be explained. As shown, according to the invention, the structure of a GaN-based light-emitting diode 30 includes a substrate 31, an n-type GaN-based layer 32, an emitting layer 33, a p-type GaN-based layer 34, a p-type contact layer 35, a textured layer 36, a window layer 37, a first electrode 38 and a second electrode 39. In the structure, a buffer layer 31′ may be additionally disposed on the substrate 31.

As described above, a semiconductor stacked layer structure formed on the substrate 31 comprises the n-type GaN-based layer 32, the emitting layer 33 and the p-type GaN-based layer 34 arranged sequentially from bottom to top. Further, the textured layer 36 is formed on the p-type GaN-based layer 34 and the p-type contact layer 35, and, as the window layer 37, a transparent conductive oxide layer is disposed on the textured layer 36, forming an ohmic contact with the textured layer. The first electrode 38 is so provided to be electrically coupled with the n-type GaN-based layer in the semiconductor stacked layer structure, and the second electrode 39 is electrically coupled with the transparent conductive oxide layer.

The substrate 31 may be a substrate made of sapphire, zinc oxide, lithium gallium oxide, lithium aluminum oxide, spinel, silicon carbide, gallium arsenide or silicon. The n-type GaN-based layer 32 may be a layer made of n-type doped gallium nitride, aluminum indium gallium nitride or indium gallium nitride. The p-type GaN-based layer 34 may be a layer made of p-type doped gallium nitride, aluminum indium gallium nitride or indium gallium nitride. The emitting layer 33 may be made of a nitride compound semiconductor containing an indium component. The window layer 37 is a transparent conductive oxide layer made of indium oxide, tin oxide or indium tin oxide.

The provision of the textured layer 36 between the p-type contact layer 35 and the window layer 37 not only enhances the light extraction efficiency, but also results in an increased light emission and interrupts the optical guiding effect because of the rugged surface thereof. Moreover, with such a surface state, during the epitaxy process, it is possible to control arbitrarily an N-polarization surface, which is described in pending Taiwanese Patent Application No. 92136888 owned by the same assignee. Thereby, the contact resistance between the window layer 37 and the second conductive GaN-based layer 34 can be reduced to form an excellent ohmic contact layer, and the working voltage of the diode can be lowered, as shown in the combination of an ITO transparent conductive layer and a textured surface and the I-V curve in Attachment 2. Furthermore, the textured layer 36 may be an n-type doped, p-type doped or double-doped GaN-based layer.

While the present invention has been described with reference to the detailed description and the drawings of the preferred examples thereof, it is to be understood that the invention should not be considered as limited thereby. Various modifications and changes could be conceived of by those skilled in the art without departuring from the scope of the present invention, which is indicated by the appended claims.

1. A GaN-based light-emitting device, comprising:
a substrate;
a semiconductor stacked layer structure disposed on said substrate, said semiconductor stacked layer structure including an n-type GaN-based layer, an emitting layer and a p-type GaN-based layer arranged sequentially from bottom to top;
a textured layer disposed on said p-type GaN-based layer;
a transparent conductive oxide layer disposed on said textured layer and forming an ohmic contact with said textured layer;
a first electrode electrically coupled with said n-type GaN-based layer in said semiconductor stacked layer structure; and
a second electrode electrically coupled with said transparent conductive oxide layer, wherein said textured layer is a N-polarization surface layer.

2. The GaN-based light-emitting device according to claim 1, wherein said textured layer is an n-type doped, p-type doped or double-doped GaN-based layer.

3. The GaN-based light-emitting device according to claim 1, wherein said transparent conductive oxide layer is made of indium oxide, tin oxide or indium tin oxide.

4. The GaN-based light-emitting device according to claim 1, wherein said emitting layer is a GaN-based layer containing an indium component.

5. (canceled)
